(19) United States
(12) Patent Application Publication
(10) Pub. No.: US 2012/0012805 A1
(43) Pub. Date: Jan. 19, 2012

(54) NONVOLATILE MEMORY DEVICE AND METHOD FOR MANUFACTURING SAME

(75) Inventors: Kazuhiko YAMAMOTO, Kanagawa-ken (JP); Kenji Aoyama, Kanagawa-ken (JP)

(73) Assignee: KABUSHIKI KAISHA TOSHIBA, Tokyo (JP)

(21) Appl. No.: 12/956,548

(22) Filed: Nov. 30, 2010

(30) Foreign Application Priority Data
Jul. 14, 2010 (JP) 2010-159642

(51) Int. Cl. H01L 45/00; H01L 21/02; B82Y 99/00

(52) U.S. Cl. 257/3; 438/381; 257/E45.001; 257/E21.002; 977/742

(57) ABSTRACT

According to one embodiment, a nonvolatile memory device includes a first interconnect, a nanomaterial aggregate layer, and a second interconnect. The nanomaterial aggregate layer is provided on the first interconnect. The nanomaterial aggregate layer includes an aggregation of a plurality of micro conductive bodies. The second interconnect is provided on the nanomaterial aggregate layer. At least a lower portion of the nanomaterial aggregate layer is disposed inside the second interconnect as viewed from above.

### CROSS-REFERENCE TO RELATED APPLICATIONS

This application is based upon and claims the benefit of priority from the prior Japanese Patent Application No. 2010-159642, filed on Jul. 14, 2010; the entire contents of which are incorporated herein by reference.

### FIELD

Embodiments described herein relate generally to a nonvolatile memory device and a method for manufacturing the same.

### BACKGROUND

In recent years, compact portable electronic devices such as mobile telephones, digital still cameras, digital video camcorders, and mobile music players are being used widely; and the amount of data handled by such electronic devices also is increasing. Therefore, the demand for compact large-capacity nonvolatile memory devices is increasing; and a huge market has been created. Even higher capacities of memory devices continue to be necessary because images handled by such electronic devices are transitioning from still images to video images and the image resolution also is increasing.

Conventionally, NAND and NOR flash memory, miniature hard disks, DVDs (Digital Versatile Discs), and the like have been used as nonvolatile memory devices. In particular, NAND flash memory has been widely used as a device suited to mobile applications because NAND flash memory is compact, can be easily provided with higher capacities, is impact-resistant, etc.

However, in flash memory, there are concerns that the characteristics may deteriorate when charge is injected and removed repeatedly to and from the recording layer. Moreover, the programming speed and the read-out speed of information are insufficient. Also, as even greater downscaling progresses to increase capacities, it is expected that operation errors may undesirably occur because the necessary amount of charge cannot be injected when reading and programming the information.

Therefore, resistance random access memory, in which a resistance state is reversibly changed to store information, is drawing attention as a device that can be downscaled and is based on an operation principle different from that of flash memory. Resistance random access memory normally includes a resistance change layer interposed between electrodes. The resistance change layer can have two or more different electrical resistance states; and the resistance state of the resistance change layer can be changed by applying a constant threshold voltage, threshold current, or threshold charge between the electrodes to record data corresponding to the difference of the resistance values thereof. The recorded data can be read non-destructively.

Data is recorded in flash memory by injecting charge to control the threshold value of a transistor. Therefore, it is necessary to provide a transistor in each of the memory cells. Conversely, resistance random access memory has a simple structure in which a resistance change layer is interposed between electrodes thereon and thereunder. Therefore, the memory cells can be stacked three-dimensionally; and it is possible to form control transistors in the same chip surface. As a result, the effective cell surface area can be reduced while increasing the recording capacity. Multicomponent metal oxides such as, for example, nickel oxide (NiO), strontium zirconate (SrZrO₃), etc., have been proposed as materials of the resistance change layer. However, the reliability is undesirably low in resistance random access memory devices using metal oxide.

### BRIEF DESCRIPTION OF THE DRAWINGS

FIG. 1 is a perspective view illustrating a nonvolatile memory device according to a first embodiment;

FIGS. 2A and 2B are cross-sectional views illustrating memory cells of the first embodiment;

FIG. 3 is a plan view illustrating the memory cell of the first embodiment;

FIG. 4 is a cross-sectional view illustrating a nanomaterial aggregate layer of the first embodiment;

FIG. 5A and FIG. 5B are cross-sectional views of processes, illustrating a method for manufacturing the nonvolatile memory device according to the first embodiment;

FIG. 6A and FIG. 6B are cross-sectional views of processes, illustrating the method for manufacturing the nonvolatile memory device according to the first embodiment;

FIG. 7A and FIG. 7B are cross-sectional views of processes, illustrating the method for manufacturing the nonvolatile memory device according to the first embodiment;

FIG. 8A and FIG. 8B are cross-sectional views of processes, illustrating the method for manufacturing the nonvolatile memory device according to the first embodiment;

FIG. 9A and FIG. 9B are cross-sectional views of processes, illustrating the method for manufacturing the nonvolatile memory device according to the first embodiment;

FIG. 10A and FIG. 10B are cross-sectional views of processes, illustrating the method for manufacturing the nonvolatile memory device according to the first embodiment;

FIGS. 11A and 11B are cross-sectional views illustrating memory cells of a second embodiment;

FIGS. 12A and 12B are cross-sectional views of processes, illustrating a method for manufacturing a nonvolatile memory device according to the second embodiment;

FIGS. 13A to 13C are cross-sectional views of processes, illustrating a method for manufacturing a nonvolatile memory device according to a third embodiment;

FIGS. 14A and 14B are cross-sectional views illustrating memory cells of a fourth embodiment; and

FIG. 15 is a cross-sectional view of a process, illustrating a method for manufacturing a nonvolatile memory device according to the fourth embodiment.

### DETAILED DESCRIPTION

In general, according to one embodiment, a nonvolatile memory device includes a first interconnect, a nanomaterial aggregate layer, and a second interconnect. The nanomaterial aggregate layer is provided on the first interconnect. The nanomaterial aggregate layer includes an aggregation of a plurality of micro conductive bodies. The second interconnect is provided on the nanomaterial aggregate layer. At least a lower portion of the nanomaterial aggregate layer is disposed inside the second interconnect as viewed from above.

According to another embodiment, a method is disclosed for manufacturing a nonvolatile memory device. The method can include forming a pillar and an inter-layer insulating film on a first interconnect. A dummy layer is provided in at least an upper portion of the pillar. The inter-layer insulating film covers a side face of the pillar and leaves an upper face of the pillar exposed. The method can include making a recess in an upper face of the inter-layer insulating film by removing the dummy layer. The method can include forming a nanomaterial aggregate layer in the recess. The nanomaterial aggregate layer has gaps interposed between a plurality of micro conductive bodies. In addition, the method can include forming a second interconnect on the inter-layer insulating film and on the nanomaterial aggregate layer to cover the nanomaterial aggregate layer.

Embodiments of the invention will now be described with reference to the drawings.

First, a first embodiment will be described.

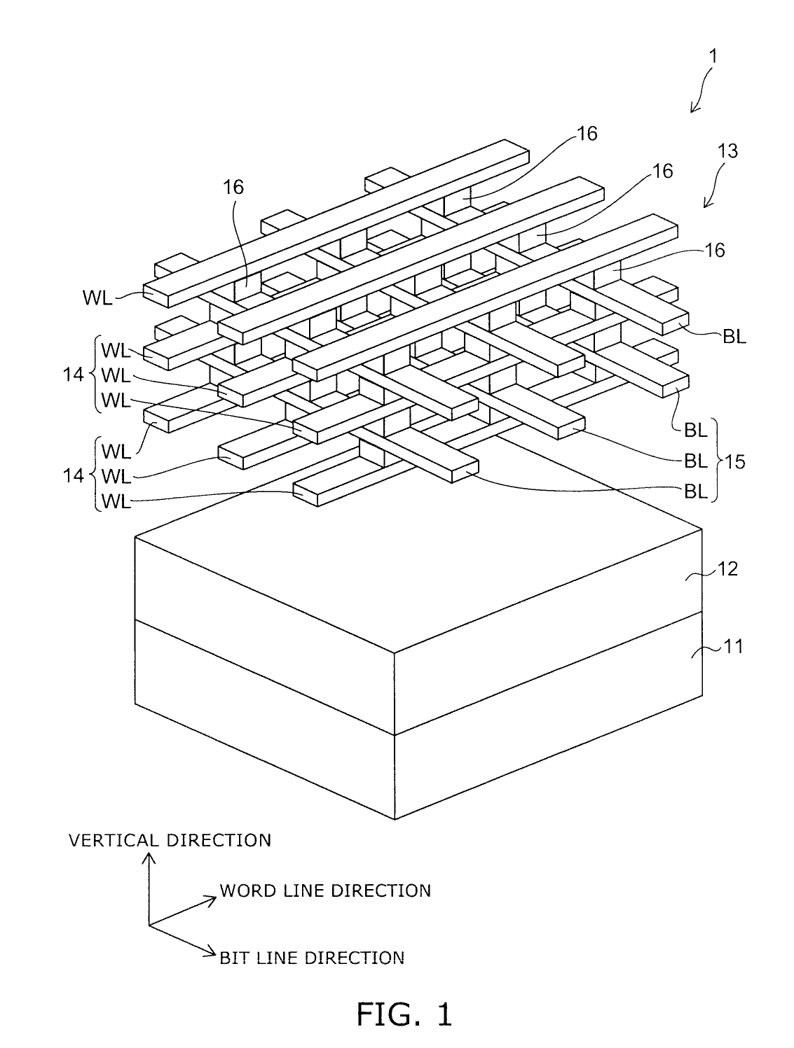

FIG. 1 is a perspective view illustrating a nonvolatile memory device according to this embodiment.

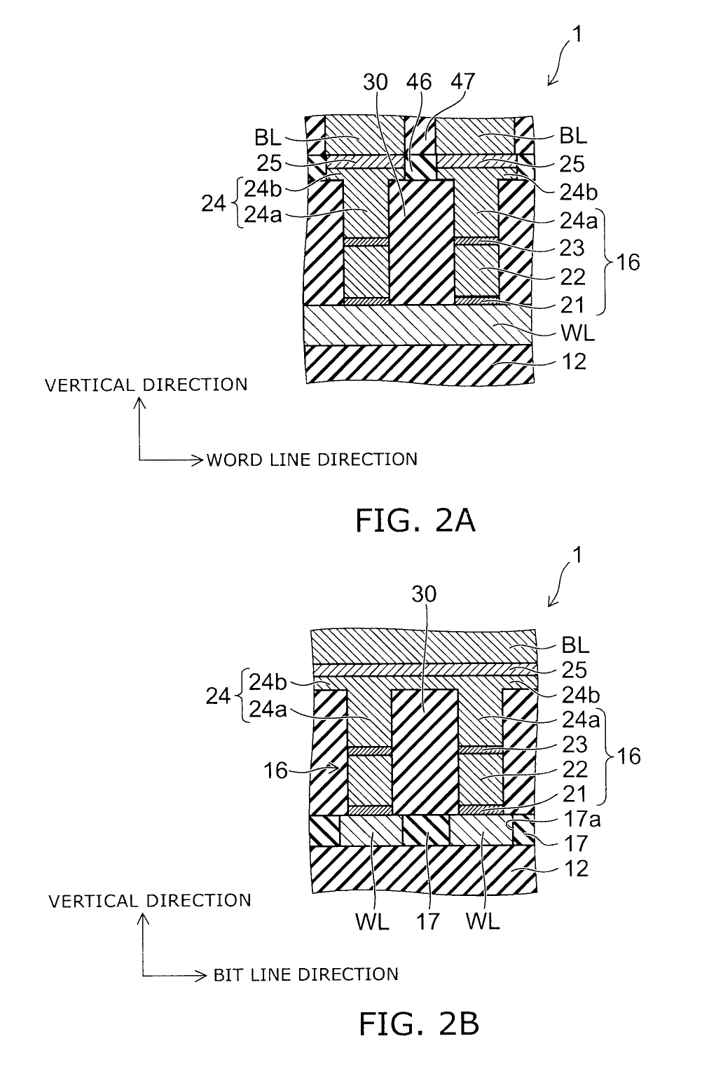

FIGS. 2A and 2B are cross-sectional views illustrating memory cells of this embodiment and illustrate mutually orthogonal cross sections.

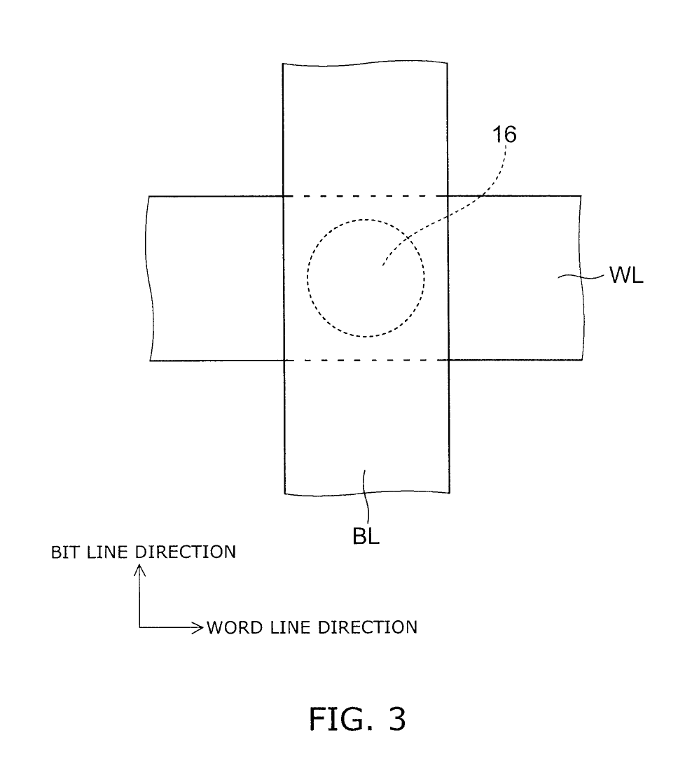

FIG. 3 is a plan view illustrating the memory cell of this embodiment.

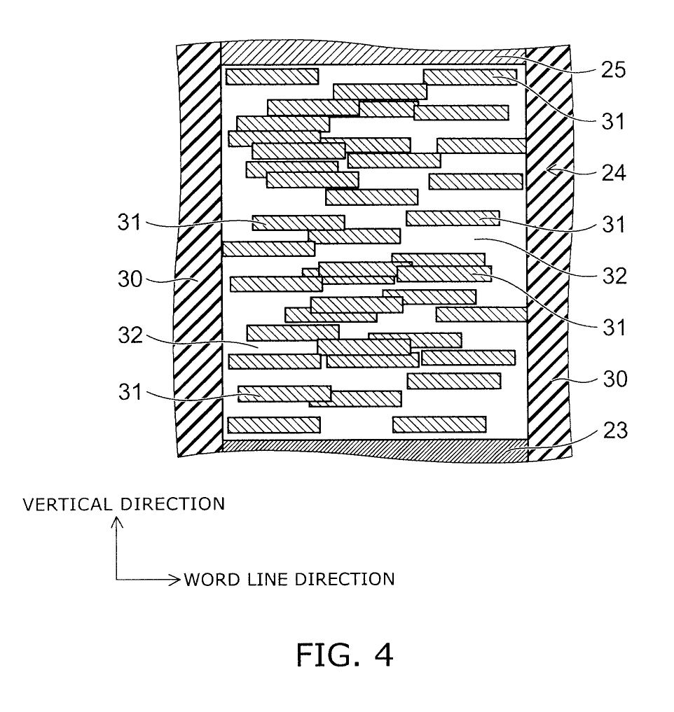

FIG. 4 is a cross-sectional view illustrating the nanomaterial aggregate layer of this embodiment.

The nonvolatile memory device according to this embodiment is a ReRAM (Resistance Random Access Memory).

First, the nonvolatile memory device according to this embodiment will be described summarily.

In the nonvolatile memory device according to this embodiment, pillars are provided between bit lines and word lines; and the pillars form memory cells. A nanomaterial aggregate layer is provided as a recording layer in each of the pillars. The nanomaterial aggregate layer is a hollow structure layer including a gap interposed between loosely aggregated carbon nanotubes (CNTs), i.e., micro conductive bodies; and each of the CNTs can move in a micro range. For example, a CNT may change its position and orientation in a space surrounded by surrounding CNTs. In the case where the CNTs are isolated from each other, the electrical resistance between the lower electrode layer and the upper electrode layer increases. On the other hand, the electrical resistance between the lower electrode layer and the upper electrode layer decreases in the case where a voltage is applied between the lower electrode layer and the upper electrode layer because adjacent CNTs contact each other due to the Coulomb forces and a current path is formed. Such a state is maintained even when the voltage is switched OFF. In this embodiment, the widths of the bit line and the word line are greater than the width of the nanomaterial aggregate layer as viewed from above. Thereby, the interconnect resistances of the bit line and the word line can be reduced while ensuring the current density of the nanomaterial aggregate layer.

A method for manufacturing the nonvolatile memory device according to this embodiment will now be described summarily.

In this embodiment, the lower electrode layer and the dummy layer are stacked on an interconnect (e.g., a word line) and subsequently patterned into a pillar by dry etching. A dummy layer is provided in the upper portion of the pillar. Then, after filling an inter-layer insulating film around the pillar, planarization is performed to expose the upper face of the pillar at the upper face of the inter-layer insulating film. Continuing, the dummy layer is removed. Thereby, a recess is made in the upper face of the inter-layer insulating film. Then, a nanomaterial in which CNTs are dispersed is coated and dried to form a nanomaterial aggregate layer in the recess. Subsequently, an interconnect (e.g., the bit line) is formed by forming a conductive film on the nanomaterial aggregate layer and patterning the conductive film to cover the nanomaterial aggregate layer. Thereby, the side face of the nanomaterial aggregate layer is not exposed to the dry etching and is not damaged. Moreover, the fluctuation of the thickness of the nanomaterial aggregate layer is low because the thickness of the nanomaterial aggregate layer is specified by the thickness of the dummy layer. Thereby, a nonvolatile memory device having high reliability can be manufactured.

The nonvolatile memory device according to this embodiment will now be described in detail.

As illustrated in FIG. 1, a silicon substrate 11 is provided in the nonvolatile memory device 1 according to this embodiment; and a drive circuit (not illustrated) of the nonvolatile memory device 1 is formed in the upper layer portion and on the upper face of the silicon substrate 11. An inter-layer insulating film 12 made of, for example, silicon oxide is provided on the silicon substrate 11 to bury the drive circuit; and a memory cell unit 13 is provided on the inter-layer insulating film 12.

In the memory cell unit 13, a word line interconnect layer 14 and a bit line interconnect layer 15 are alternately stacked with an inter-layer insulating film 30 (referring to FIGS. 2A and 2B) interposed therebetween, where the word line interconnect layer 14 includes multiple word lines WL extending in one direction (hereinbelow referred to as the word line direction) parallel to the upper face of the silicon substrate 11, and the bit line interconnect layer 15 includes multiple bit lines BL extending in a direction (hereinbelow referred to as the bit line direction) parallel to the upper face of the silicon substrate 11 and intersecting, e.g., being orthogonal to, the word line direction. The word lines WL do not contact each other; the bit lines BL do not contact each other; and the word lines WL do not contact the bit lines BL.

A pillar 16 extending in a direction (hereinbelow referred to as the vertical direction) perpendicular to the upper face of the silicon substrate 11 is provided at the points where each of the word lines WL and each of the bit lines BL are most proximal. The pillar 16 is connected between the word line WL and the bit line BL. One memory cell includes one of the pillars 16. In other words, the nonvolatile memory device 1 is a cross-point device in which memory cells are disposed at each of the points where the word lines WL and the bit lines BL are most proximal. The inter-layer insulating film 30 (referring to FIGS. 2A and 2B) is filled into the space between the word line WL, the bit line BL, and the pillar 16.

The configuration of the pillar 16 will now be described.

As illustrated in FIGS. 2A and 2B, the configuration of the pillar 16 is a columnar configuration, e.g., a circular columnar configuration, extending in the vertical direction. The diameter of the pillar 16 is, for example, 20 to 100 nm. In each of the pillars 16, a barrier metal layer 21, a silicon diode layer 22, a lower electrode layer 23, and a nanomaterial aggregate layer 24 are stacked in this order from the bottom upward. Hereinbelow, an example is described in which the word line WL is disposed below the pillar 16 and the bit line BL is disposed above the pillar 16.

The barrier metal layer 21 contacts the word line WL (referring to FIG. 1). A lower portion 24a of the nanomaterial aggregate layer 24 is included in the upper portion of the pillar 16; and an upper portion 24b of the nanomaterial aggregate layer 24 juts in the word line direction from the region directly on the pillar 16 and extends in the bit line direction above the pillar 16. Thereby, the upper portion 24b of the nanomaterial aggregate layer 24 is disposed in the region directly under the bit line BL. An upper electrode layer 25 is provided in the region directly on the upper portion 24b. The upper electrode layer 25 contacts the bit line BL (referring to FIG. 1). In other words, the upper portion 24b of the nanomaterial aggregate layer 24 and the upper electrode layer 25 are provided commonly for multiple pillars 16 arranged in the bit line direction. The height of the lower portion 24a is, for example, 20 to 50 nm.

The barrier metal layer 21 is made of a two-layer film in which, for example, a titanium nitride (TiN) layer is stacked on a titanium (Ti) layer. The silicon diode layer 22 is a selection element layer that selects whether or not a current is allowed to flow. The silicon diode layer 22 is made of, for example, polysilicon in which an n-type layer having an n⁺-type conductivity type, an i-type layer made of an intrinsic semiconductor, and a p-type layer having a p⁺-type conductivity type are stacked in order from the lower layer side. Thereby, the silicon diode layer 22 functions as a selection element layer that allows a current to flow only in the case where a potential higher than that of the word line WL is supplied to the bit line BL and does not allow a current to flow in the reverse direction. The lower electrode layer 23 and the upper electrode layer 25 are formed of conductive materials such as tungsten or titanium nitride.

As illustrated in FIG. 4 as described above, the nanomaterial aggregate layer 24 is a layer of a gap 32 interposed between an aggregation of CNTs (carbon nanotubes) 31 rather than being a continuous layer made of a single conductor material. The gap 32 is a layer including nitrogen gas (N₂) or hydrogen gas (H₂). Accordingly, the structure of the nanomaterial aggregate layer 24 is a hollow structure. The configuration of each of the CNTs 31 is cylindrical with a diameter of, for example, 1 to 2 nm and a length of, for example, 20 to 30 nm. For example, in the case where the diameter of the CNT 31 is 2 nm, it is desirable for the height of the lower portion 24a to be about 50 nm to ensure the resistance value of the nanomaterial aggregate layer 24. It is desirable for the length of the CNT 31 to be shorter than the diameter of the lower portion 24a of the nanomaterial aggregate layer 24. The CNT 31 extends roughly in a horizontal direction, i.e., a direction parallel to the plane of the word line direction and the bit line direction. The number of stacks of the CNT 31 in the thickness direction of the nanomaterial aggregate layer 24 is, for example, about several layers to several tens of layers.

Then, as illustrated in FIGS. 2A and 2B and FIG. 3, the width of the pillar 16 is finer than the width of the word line WL and finer than the width of the bit line BL as viewed from above. Thereby, the pillar 16 is disposed inside the word line WL and the bit line BL as viewed from above. In other words, the barrier metal layer 21, the silicon diode layer 22, the lower electrode layer 23, and the lower portion 24a of the nanomaterial aggregate layer 24 included in the pillar 16 are disposed inside the upper portion 24b of the nanomaterial aggregate layer 24, the upper electrode layer 25, the word line WL, and the bit line BL as viewed from above. For convenience of illustration in FIG. 1, the widths of the word line WL, the bit line BL, and the pillar 16 are illustrated as being substantially equal.

A method for manufacturing the nonvolatile memory device according to this embodiment will now be described.

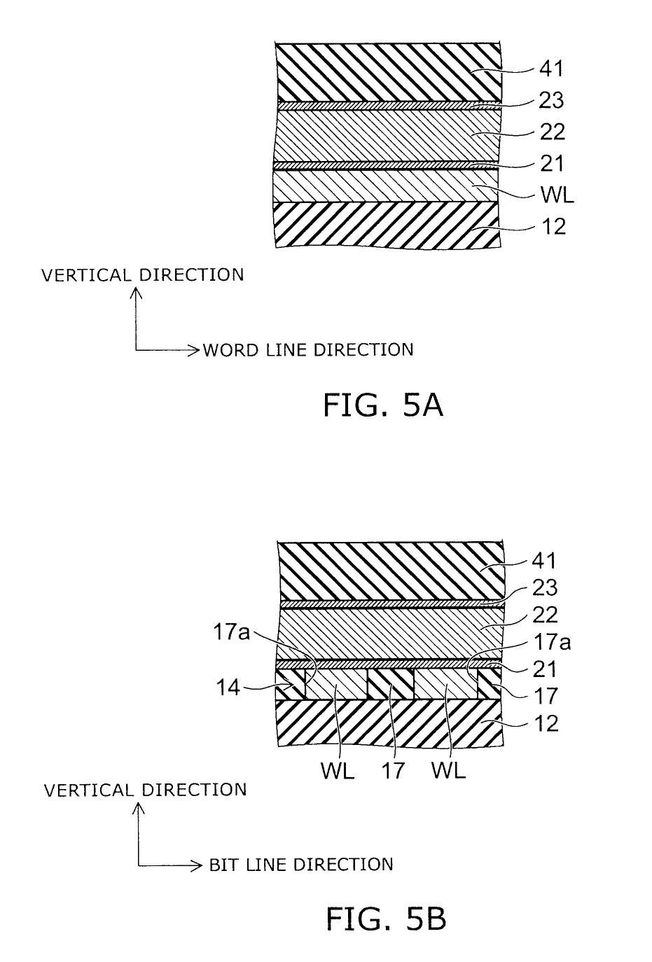

FIG. 5A to FIG. 10B are cross-sectional views of processes, illustrating the method for manufacturing the nonvolatile memory device according to this embodiment. Drawing A and drawing B of each of the drawings illustrate mutually orthogonal cross sections.

First, the silicon substrate 11 is prepared as illustrated in FIG. 1. The silicon substrate 11 is, for example, a portion of a silicon wafer. Then, a drive circuit for driving the memory cell unit 13 is formed on the upper face of the silicon substrate 11. Continuing, the inter-layer insulating film 12 is formed on the silicon substrate 11.

Then, as illustrated in FIGS. 5A and 5B, an inter-layer insulating film 17 is formed on the inter-layer insulating film 12. Continuing, multiple trenches 17a extending in the word line direction are made in the upper face of the inter-layer insulating film 17 by etching using a resist pattern as a mask. Then, a conductive material such as, for example, tungsten is deposited on the entire surface to form a conductive film. Continuing, CMP (chemical mechanical polishing) is performed on the upper face of the conductive film to remove the portion of the conductive film deposited on the upper face of the inter-layer insulating film 17 and leave the portion deposited in the trench 17a. Thereby, the multiple word lines WL are formed in the trenches 17a and separated from each other by the inter-layer insulating film 17. The word line interconnect layer 14 is formed of these word lines WL.

Then, the barrier metal layer 21 is formed by depositing, for example, titanium and titanium nitride on the word line interconnect layer 14. Continuing, amorphous silicon is deposited on the barrier metal layer 21. At this time, an n-type layer, an i-type layer, and a p-type layer are continuously formed by introducing each of the impurities while depositing the amorphous silicon. Thereby, the silicon diode layer 22 is formed. The barrier metal layer 21 is a layer that suppresses the reaction between the tungsten of the word line WL and the silicon of the silicon diode layer 22 while increasing the adhesion between the word line WL and the silicon diode layer 22. Then, a conductive material such as tungsten or titanium nitride is deposited on the silicon diode layer 22 to form the lower electrode layer 23.

Continuing, a dummy layer 41 is formed on the lower electrode layer 23. It is sufficient for the dummy layer 41 to be a material having etching selectivity with the lower electrode layer 23 and with the inter-layer insulating film 30 (referring to FIGS. 2A and 2B) formed in a subsequent process; and the dummy layer 41 may be, for example, a single layer or a composite layer made of silicon nitride (SiN), polysilicon, or carbon (C). The barrier metal layer 21, the silicon diode layer 22, the lower electrode layer 23, and the dummy layer 41 may be formed by CVD and may be formed by sputtering.

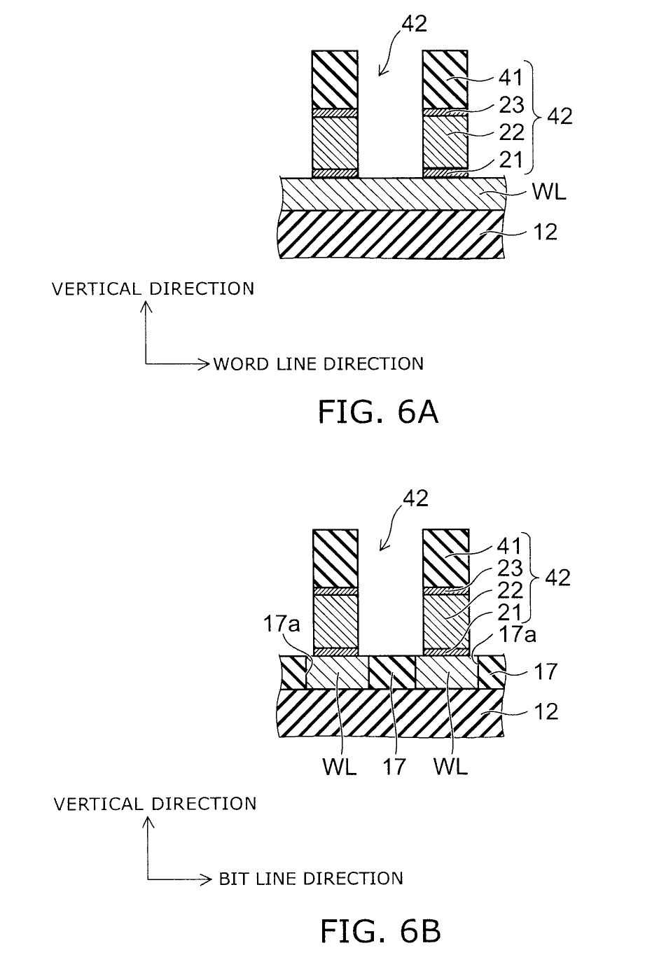

Then, as illustrated in FIGS. 6A and 6B, a resist pattern is formed on the dummy layer 41 and dry etching is performed by, for example, RIE (reactive ion etching) and the like using the resist pattern as a mask. Thereby, the dummy layer 41, the lower electrode layer 23, the silicon diode layer 22, and the barrier metal layer 21 are selectively removed to form a pillar 42. The pillars 42 are formed in the regions where the pillars 16 (referring to FIG. 1) are to be formed in a matrix configuration periodically arranged along both the word line direction and the bit line direction. The configuration of each of the pillars 16 is, for example, a circular columnar configuration.

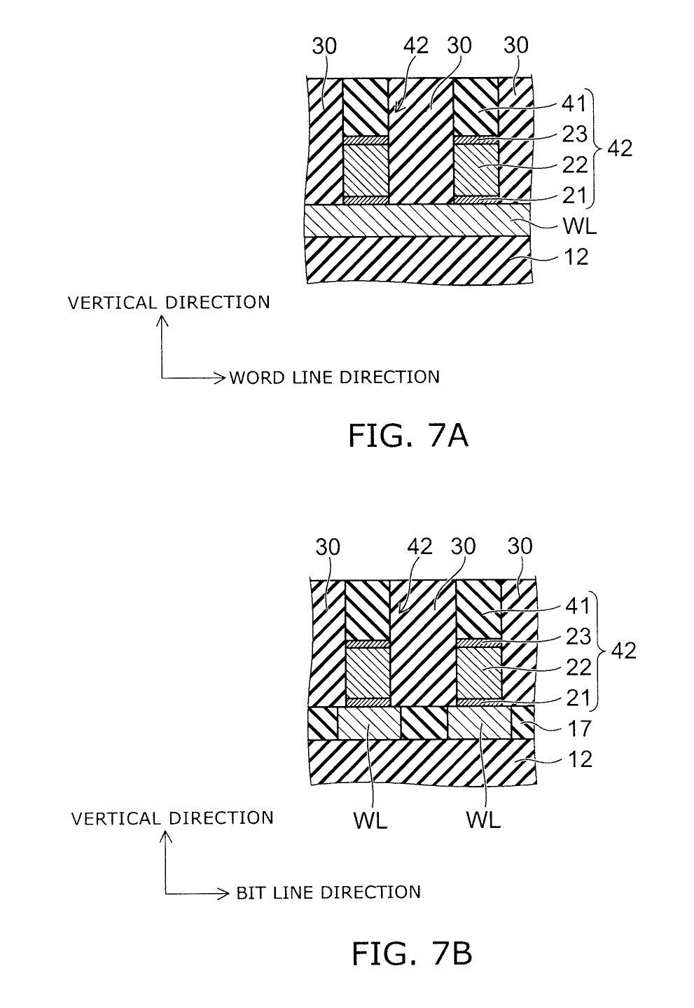

Continuing as illustrated in FIGS. 7A and 7B, the inter-layer insulating film 30 is formed around the pillar 42 by depositing, for example, silicon oxide. Thereby, the pillar 42 is buried in the inter-layer insulating film 30. Then, CMP is performed to planarize the upper face of the inter-layer insulating film 30 to expose the dummy layer 41 from the upper face of the inter-layer insulating film 30. In other words, at this stage, the inter-layer insulating film 30 covers the side face of the pillar 42 and leaves the upper face of the inter-layer insulating film 30 exposed.

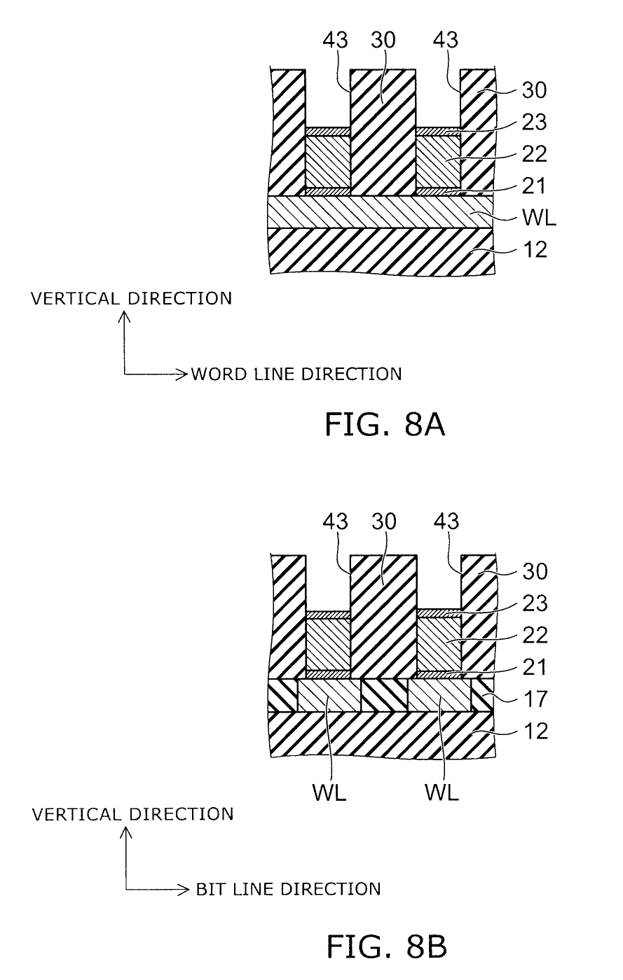

Then, as illustrated in FIGS. 8A and 8B, the dummy layer 41 (referring to FIGS. 7A and 7B) is removed. For example, in the case where the dummy layer 41 is formed of silicon nitride, the dummy layer 41 can be selectively removed substantially without etching the inter-layer insulating film 30 and the lower electrode layer 23 by performing wet etching using hot phosphoric acid. Thereby, a recess 43 is made in the upper face of the inter-layer insulating film 30. The lower electrode layer 23 is exposed at the bottom face of the recess 43.

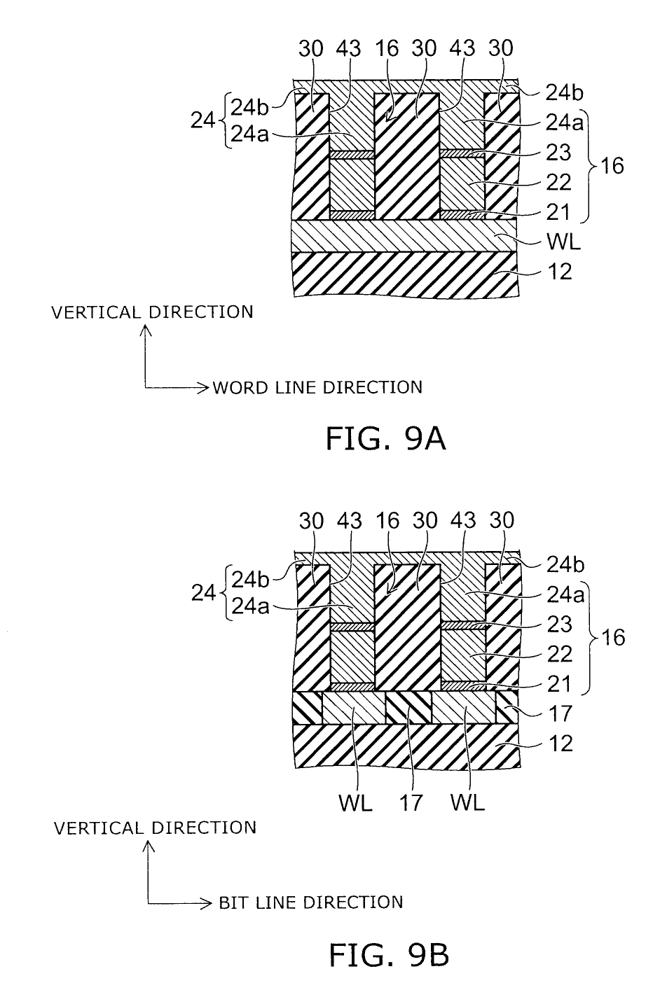

Continuing as illustrated in FIGS. 9A and 9B, a nanomaterial containing many carbon nanotubes (CNTs) is prepared. The nanomaterial may include, for example, a dispersion solution of CNTs dispersed in water. Then, the dispersion solution is coated on the upper face of the inter-layer insulating film 30. At this time, the dispersion solution fills the interior of the recess 43 and is disposed also on the upper face of the inter-layer insulating film 30. Then, baking is performed to evaporate the water from the dispersion solution. Thereby, a thin nanomaterial aggregate layer is formed in the recess 43 and on the upper face of the inter-layer insulating film 30. In the nanomaterial aggregate layer, the multiple CNTs 31 (referring to FIG. 4) are loosely bonded by Van der Waals forces; and the gap 32 (referring to FIG. 4) is formed between the CNTs 31. The direction in which the CNTs 31 extend approaches the horizontal direction as the dispersion solution dries and the thickness decreases.

The coating and the baking of the dispersion solution are multiply repeated to stack thin nanomaterial aggregate layers in multiple layers to fill the recess 43; and the nanomaterial aggregate layer 24 is formed in the recess 43 without voids. The nanomaterial aggregate layer 24 is formed also on the upper face of the inter-layer insulating film 30. In other words, the lower portion 24a of the nanomaterial aggregate layer 24 is disposed in the recess 43; and the upper portion 24b is disposed on the upper face of the inter-layer insulating film 30. Thereby, the barrier metal layer 21, the silicon diode layer 22, the lower electrode layer 23, and the lower portion 24a of the nanomaterial aggregate layer 24 are stacked in this order to form the pillar 16.

When forming the nanomaterial aggregate layer 24, it is favorable for the dispersion solution to be coated as thinly as possible in each of the coating processes and for the number of times the dispersion solution is coated and baked to be as high as possible. Thereby, the distance that each of the CNTs 31 extends in the vertical direction is reduced; more contact points between the CNTs 31 are provided; and the range of the resistance change of the entire nanomaterial aggregate layer 24 can be increased.

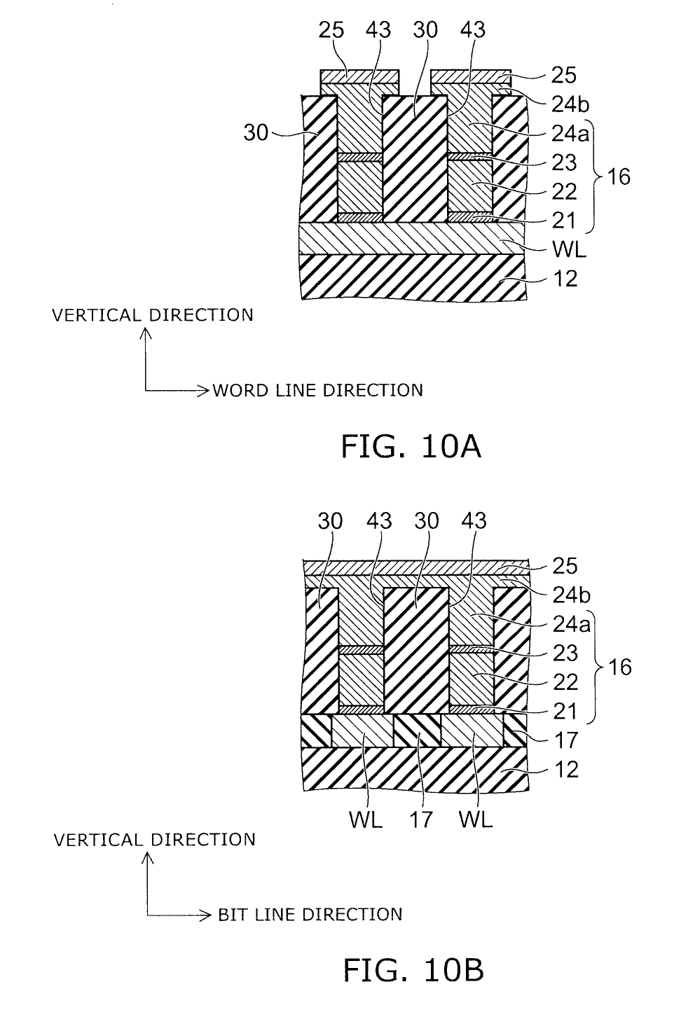

Then, as illustrated in FIGS. 10A and 10B, a conductive material such as tungsten is deposited on the nanomaterial aggregate layer 24 to form the upper electrode layer 25. Then, the upper electrode layer 25 and the upper portion 24b of the nanomaterial aggregate layer 24 are patterned to cover the lower portion 24a of the nanomaterial aggregate layer 24 formed in the recess 43. In other words, the patterning is performed such that the outer edges of the upper electrode layer 25 and the upper portion 24b are positioned outside the outer edge of the lower portion 24a as viewed from above. Thereby, the upper portion 24b of the nanomaterial aggregate layer 24 and the upper electrode layer 25 are patterned into a line configuration extending in the bit line direction.

Continuing as illustrated in FIGS. 2A and 2B, an inter-layer insulating film 46 is formed on the inter-layer insulating film 30 to cover the upper electrode layer 25. Then, CMP is performed on the upper face of the inter-layer insulating film 46 to expose the upper electrode layer 25. Continuing, the bit line BL is formed in the region directly on the upper electrode layer 25 by forming a conductive film by depositing a conductive material such as tungsten on the entire surface and by patterning the conductive film. The bit line interconnect layer 15 is formed of such multiple bit lines BL. Then, an inter-layer insulating film 47 is formed on the inter-layer insulating film 46 to cover the bit lines BL; and CMP is performed to expose the bit lines BL.

Then, as illustrated in FIG. 1, the pillar 16 is formed on the bit line BL. When forming the pillar 16, the order of the stacking of the n-type layer, the i-type layer, and the p-type layer of the silicon diode layer 22 is reversed from that of the pillar 16 formed on the word line WL described above. Thereafter, similar methods are used to repeatedly form the word line interconnect layer 14, the multiple pillars 16, the bit line interconnect layer 15, and the multiple pillars 16. Thereby, the nonvolatile memory device 1 according to this embodiment is manufactured.

Operations of this embodiment will now be described.

In the nonvolatile memory device 1 according to this embodiment, the nanomaterial aggregate layer 24 can have two states of a “high resistance state” and a “low resistance state.” The mechanism, while not completely elucidated, is considered to be, for example, as follows.

When a voltage is not applied between the lower electrode layer 23 and the upper electrode layer 25, the CNTs 31 of the nanomaterial aggregate layer 24 are roughly in a state of being isolated from each other; and the nanomaterial aggregate layer 24 is in the “high resistance state.” On the other hand, when a voltage is applied between the lower electrode layer 23 and the upper electrode layer 25, Coulomb forces occur between the CNTs 31; and the CNTs 31 attract each other. Then, when the voltage is continuously applied for at least a constant amount of time, the CNTs 31 move and rotate due to the Coulomb forces and contact adjacent CNTs 31; and a current path is formed between the lower electrode layer 23 and the upper electrode layer 25 via the multiple CNTs 31. As a result, the nanomaterial aggregate layer 24 is switched to the “low resistance state.” This state is maintained even when the voltage is no longer applied between the lower electrode layer 23 and the upper electrode layer 25. When a short pulse voltage, e.g., on the order of nanoseconds, is applied between the lower electrode layer 23 and the upper electrode layer 25, the contact portions between the CNTs 31 generate heat; and the CNTs 31 separate from each other. As a result, the nanomaterial aggregate layer 24 returns to the “high resistance state.” Thus, the nanomaterial aggregate layer 24 can have the two states of the “high resistance state” and the “low resistance state.” Thereby, binary data can be stored.

Effects of this embodiment will now be described.

According to this embodiment, a resistance change layer is formed of carbon nanotubes (CNTs). Thereby, a ReRAM is realized. In conventional resistance change layers using metal oxides, operations were unfortunately unstable because metal oxides normally are insulators. Conversely, according to this embodiment, it is possible to drive with a low voltage and the operations are stable because the resistance change layer is formed using CNTs which are conductors. Thereby, a nonvolatile memory device having high reliability can be realized.

In this embodiment, the lower portion 24a of the nanomaterial aggregate layer 24 is disposed inside the word line WL and the bit line BL as viewed from above. Thereby, the pillar 16 can be finer than the word line WL and the bit line BL. As a result, the amount of current can be reduced while ensuring the current density necessary for switching between the “high resistance state” and the “low resistance state” in the nanomaterial aggregate layer 24. On the other hand, the word line WL and the bit line BL can be relatively wide to reduce the interconnect resistance. Thereby, the amount of current and the resistance value when providing current to the word line WL and the bit line BL can be reduced; and the voltage drop amount can be reduced. As a result, stable operations of the nonvolatile memory device 1 can be maintained even for higher integration of the memory cells.

Further, in this embodiment, the recess 43 is made in the upper face of the inter-layer insulating film 30 by forming the pillar 42 having the dummy layer 41 provided in the upper portion thereof, using the inter-layer insulating film 30 to bury the pillar 42, and subsequently removing the dummy layer 41. Then, the nanomaterial including the CNTs 31 is filled into the recess 43 to form the nanomaterial aggregate layer 24. Accordingly, when forming the nanomaterial aggregate layer 24, the nanomaterial aggregate layer 24 is not damaged due to etching because the nanomaterial aggregate layer 24 is not etched. As a result, the introduction of defects into the nanomaterial aggregate layer 24 is suppressed; and the reliability of the nonvolatile memory device 1 can be increased.

Conversely, supposing that the pillar 16 is to be formed by stacking the barrier metal layer 21, the silicon diode layer 22, the lower electrode layer 23, and the nanomaterial aggregate layer 24 in this order and by patterning these stacked films using dry etching, the side face of the nanomaterial aggregate layer 24 would be exposed to the plasma atmosphere during the dry etching. However, the nanomaterial aggregate layer 24 is physically and chemically fragile because the nanomaterial aggregate layer 24 includes the gap 32 interposed between the loosely-bonded CNTs 31. Therefore, the side face of the nanomaterial aggregate layer 24 is damaged by contact with plasma, adhesion of by-products, electrostatic charge due to the storing of charge, etc.; unrestorable defects, for example, are introduced; and the memory cell characteristics undesirably deteriorate.

Also, in methods which thus form the nanomaterial aggregate layer 24 as a film in a wide region, internal stress occurs in the nanomaterial aggregate layer 24 when forming the film and in the subsequent cooling. Then, in the case where the adhesion between the nanomaterial aggregate layer 24 and the lower electrode layer 23 is insufficient, the nanomaterial aggregate layer 24 undesirably deforms and peels from the lower electrode layer 23. Therefore, contrivances are necessary such as using a thin nanomaterial aggregate layer 24, adjusting the composition, etc., to ensure the adhesion; and the degrees of freedom of the design decrease.

Conversely, according to this embodiment, because the nanomaterial aggregate layer 24 is filled into the recess 43, the internal stress is lower than when formed as a film in a wide region. Even in the case where the adhesion between the lower electrode layer 23 and the nanomaterial aggregate layer 24 is low, the peeling does not occur easily because the position and the configuration of the nanomaterial aggregate layer 24 are specified by the recess 43.

Further, generally, in the case where a liquid material is coated, it is difficult to have a constant coating thickness. For example, the coating thickness proximal to the nozzle supplying the liquid material is thick; and the coating thickness is thinner away from the nozzle. Also, in the case where the liquid material is coated onto a wafer by spin coating, the coating thickness is thickest at the center of the wafer; and the coating thickness is thinner at the edge portion of the wafer. However, according to this embodiment, the thickness of the nanomaterial aggregate layer 24 can be specified by the depth of the recess 43, i.e., the thickness of the dummy layer 41, because the nanomaterial aggregate layer 24 is formed by filling the nanomaterial into the recess 43. It is easy to control the thickness of the dummy layer 41 because the dummy layer 41 is formed by depositing, for example, silicon nitride using CVD. As a result, the thickness of the nanomaterial aggregate layer 24 can be uniform between the pillars 16; and the reliability of the operations of the nonvolatile memory device 1 can be increased.

Moreover, because the nanomaterial aggregate layer 24 is formed by coating in this embodiment, voids (pores) do not form in the central portion of the recess 43 as viewed from above, which is different from the case of the nanomaterial aggregate layer 24 being formed by vapor deposition methods such as CVD and sputtering. In particular, the coating and drying of the nanomaterial are multiply repeated to reliably prevent the occurrence of voids. As a result, the nanomaterial aggregate layer 24 can be formed homogeneously; and the device structure and the electrical characteristics of each of the memory cells can be stabilized.

Although an example is illustrated in this embodiment in which the dummy layer 41 is formed of silicon nitride, the inter-layer insulating film 30 is formed of silicon oxide, and only the silicon nitride is removed selectively using hot phosphoric acid, the combination of the material of the dummy layer 41, the material of the inter-layer insulating film 30, and the removal method of the dummy layer 41 is not limited thereto. For example, the dummy layer 41 may be formed of BPSG (boron phosphorous silicate glass), the inter-layer insulating film 30 may be formed of silicon oxide having TEOS (tetra ethyl ortho silicate) as a source material, etching may be performed using vaporous hydrofluoric acid or dilute hydrofluoric acid solution, and the BPSG may be removed selectively utilizing the difference of etching rates. Or, the dummy layer 41 may be formed of metallic tungsten, the inter-layer insulating film 30 may be formed of silicon oxide, and only the metallic tungsten may be removed by performing wet etching using a mixed liquid of aqueous hydrogen peroxide (H₂O₂), ammonia, and water. Further, the metallic tungsten may be removed using dry etching.

A second embodiment will now be described.

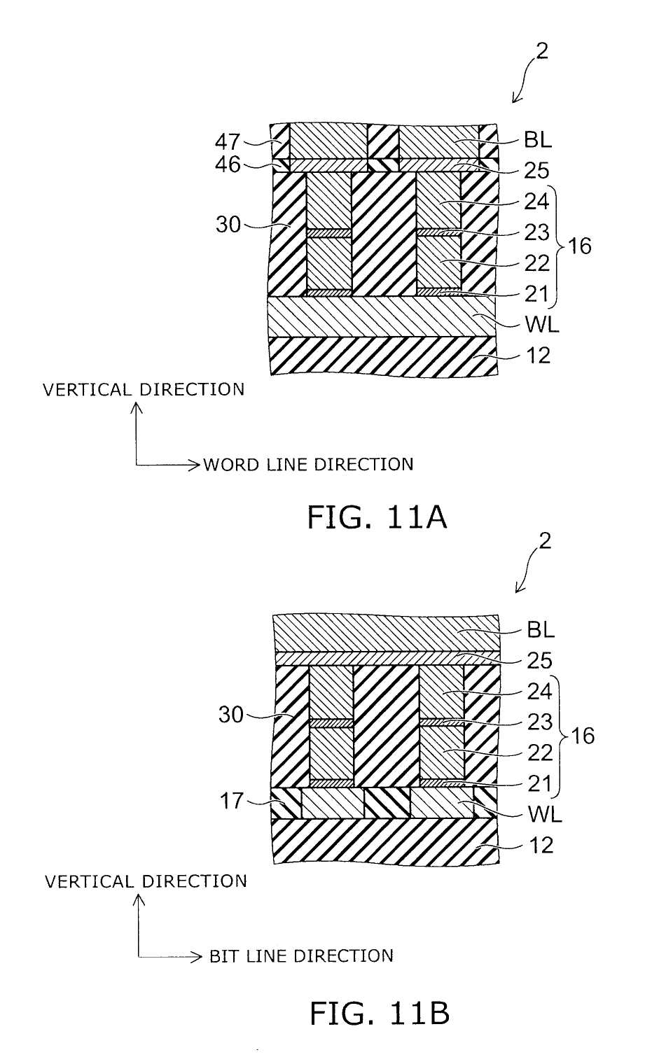

FIGS. 11A and 11B are cross-sectional views illustrating memory cells of this embodiment, and illustrate mutually orthogonal cross sections.

As illustrated in FIGS. 11A and 11B, a nonvolatile memory device 2 according to this embodiment differs from the nonvolatile memory device 1 according to the first embodiment described above (referring to FIGS. 2A and 2B) in that the upper portion 24b of the nanomaterial aggregate layer 24 is not provided. In other words, in the nonvolatile memory device 2, the entire nanomaterial aggregate layer 24 is buried in the inter-layer insulating film 30 and is a portion of the pillar 16.

A method for manufacturing the nonvolatile memory device according to this embodiment will now be described.

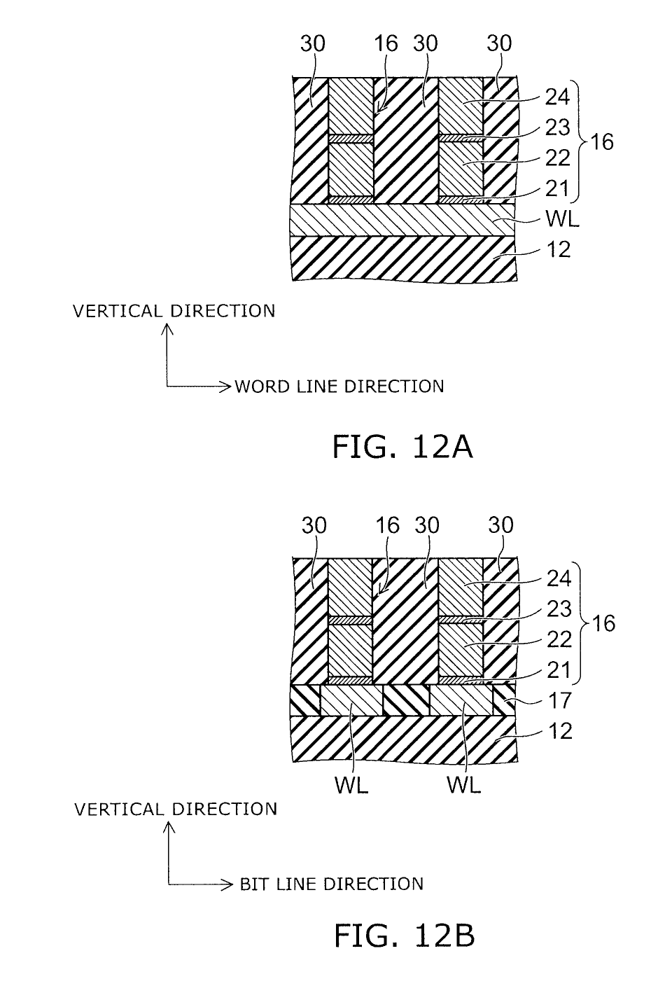

FIGS. 12A and 12B are cross-sectional views of processes, illustrating the method for manufacturing the nonvolatile memory device according to this embodiment.

First, the method described in regard to the first embodiment described above is implemented up to the process illustrated in FIGS. 9A and 9B. In other words, as illustrated in FIGS. 9A and 9B, the nanomaterial aggregate layer 24 is formed in the recess 43 and on the upper face of the inter-layer insulating film 30.

Then, as illustrated in FIGS. 12A and 12B, the upper face of the inter-layer insulating film 30 is exposed by planarizing the entire surface using CMP and the like. In other words, the upper face of the nanomaterial aggregate layer 24 is made to be the same plane as the upper face of the inter-layer insulating film 30. Thereby, the upper portion 24b of the nanomaterial aggregate layer 24 (referring to FIGS. 9A and 9B) is removed; and only the lower portion 24a filled into the recess 43 remains. The manufacturing method thereinafter is similar to that of the first embodiment.

According to this embodiment, the quality of the nanomaterial aggregate layer 24 can be improved because no portion of the nanomaterial aggregate layer 24 is exposed to the etching. Also, because the upper portion 24b does not exist, the thickness of the nanomaterial aggregate layer 24 can be controlled with better precision. Otherwise, the configurations, manufacturing methods, operations, and effects of this embodiment are similar to those of the first embodiment described above.

A third embodiment will now be described.

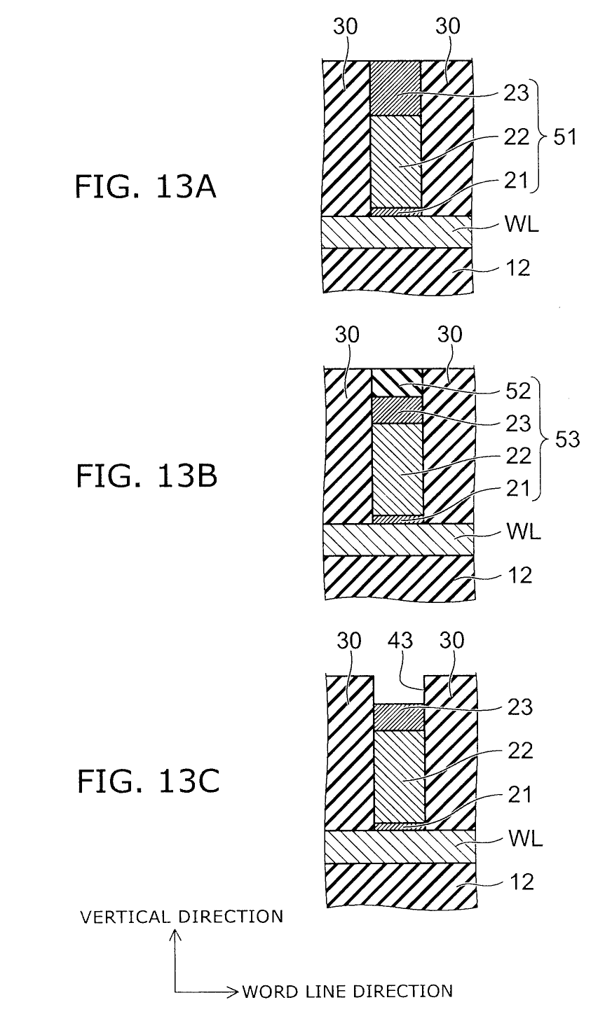

FIGS. 13A to 13C are cross-sectional views of processes, illustrating the method for manufacturing the nonvolatile memory device according to this embodiment.

This embodiment differs from the first embodiment described above in that the dummy layer is formed by oxidizing the upper portion of the lower electrode layer 23 after the pillar patterning instead of patterning the pillar after forming the dummy layer 41 (referring to FIG. 5A to FIG. 7B).

In other words, as illustrated in FIG. 13A, the barrier metal layer 21, the silicon diode layer 22, and the lower electrode layer 23 are stacked in this order on the word line interconnect layer 14. Then, a resist pattern (not illustrated) is formed on the lower electrode layer 23; and a pillar 51 is formed by selectively removing the lower electrode layer 23, the silicon diode layer 22, and the barrier metal layer 21 by performing etching using the resist pattern as a mask. Continuing, the inter-layer insulating film 30 is formed to bury the pillar 51; and CMP of the upper face is performed to expose the lower electrode layer 23. Etch-back of the inter-layer insulating film 30 may be performed instead of CMP.

Then, as illustrated in FIG. 13B, the upper portion of the lower electrode layer 23 is oxidized by performing oxygen plasma processing or by performing heat treatment in an oxygen atmosphere. Thereby, the upper portion of the lower electrode layer 23 is changed into a dummy layer 52 made of metal oxide. In other words, a pillar 53 is formed in which the upper portion is made of the dummy layer 52.

Continuing as illustrated in FIG. 13C, the dummy layer 52 is removed by performing, for example, wet processing. Thereby, the recess 43 is made in the upper face of the inter-layer insulating film 30. The subsequent processes are similar to those of the first embodiment described above.

In this embodiment as well, effects similar to those of the first embodiment described above can be obtained. Otherwise, the configurations, manufacturing methods, operations, and effects of this embodiment are similar to those of the first embodiment described above.

A fourth embodiment will now be described.

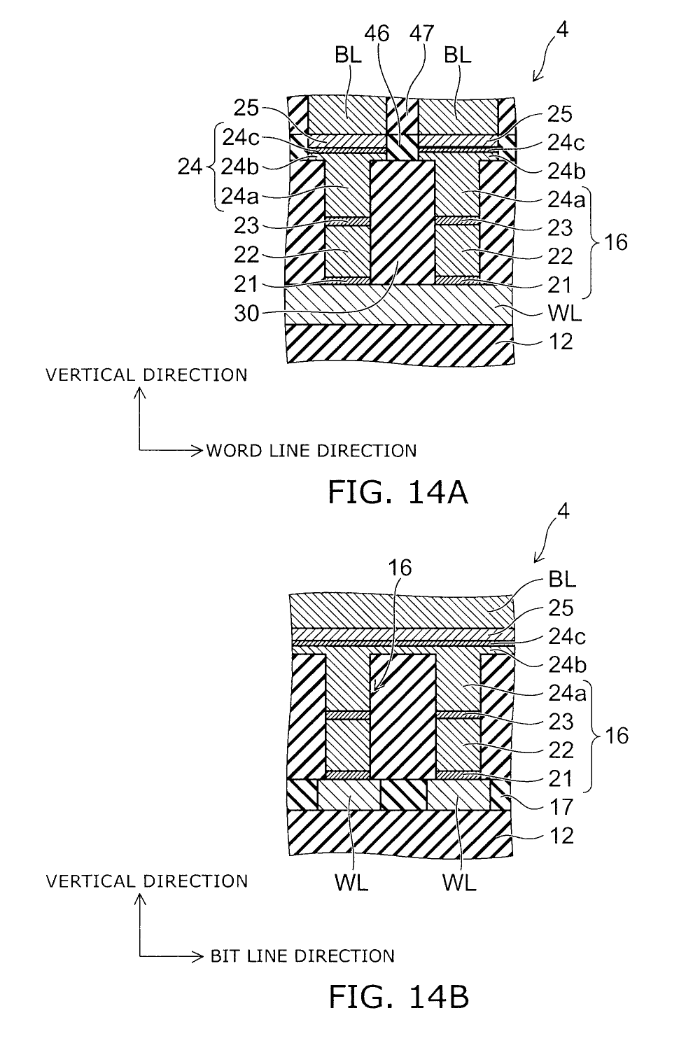

FIGS. 14A and 14B are cross-sectional views illustrating memory cells of this embodiment.

As illustrated in FIGS. 14A and 14B, a nonvolatile memory device 4 according to this embodiment differs from the nonvolatile memory device 1 according to the first embodiment described above (referring to FIGS. 2A and 2B) in that a high density layer 24c is formed in the upper portion of the upper portion 24b of the nanomaterial aggregate layer 24. The density of the high density layer 24c is, for example, not less than 2.0 g/cm³, e.g., 2.0 to 2.2 g/cm³. On the other hand, the density of the portion of the nanomaterial aggregate layer 24 other than the high density layer 24c is, for example, not more than 1.8 g/cm³, e.g., 1.5 to 1.8 g/cm³. The total length of the CNTs 31 per unit volume of the high density layer 24c is longer than the total length of the CNTs 31 per unit volume of the portion of the nanomaterial aggregate layer 24 other than the high density layer 24c.

A method for manufacturing the nonvolatile memory device according to this embodiment will now be described.

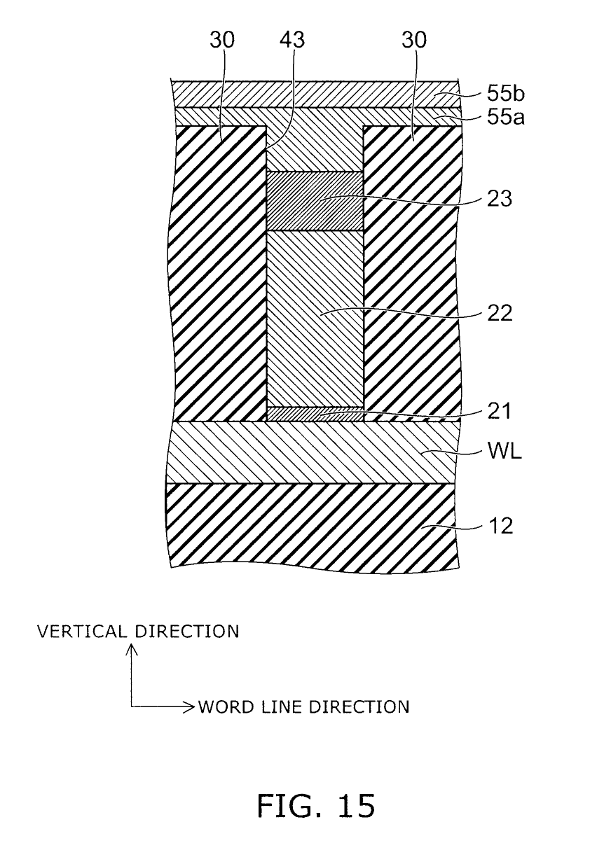

FIG. 15 is a cross-sectional view of a process, illustrating the method for manufacturing the nonvolatile memory device according to this embodiment.

In this embodiment as illustrated in FIG. 15, in the process illustrated in FIGS. 9A and 9B of the first embodiment described above, first, a low density layer 55a having a relatively low density is formed as a film; and then a high density layer 55b having a relatively high density is formed as a film. For example, the low density layer 55a can be formed by using a thick coating thickness for each coating process and by coating and drying fewer times. On the other hand, the high density layer 55b can be formed using a thin coating thickness for each coating process and by coating and drying more times. The low density layer 55a is the lower portion 24a and the lower portion of the upper portion 24b of the nanomaterial aggregate layer 24; and the high density layer 55b is the high density layer 24c of the nanomaterial aggregate layer 24.

According to this embodiment, the penetration of atoms of tungsten and the like into the interior of the nanomaterial aggregate layer 24 can be suppressed when forming the upper electrode layer 25 using a vapor deposition method such as CVD after forming the nanomaterial aggregate layer 24. In other words, it is difficult for the conductive material to penetrate deeply because the high density layer 24c is provided in the nanomaterial aggregate layer 24 because the gap 32 between the CNTs 31 is narrow in the high density layer 24c. Thereby, the interface between the nanomaterial aggregate layer 24 and the upper electrode layer 25 can be flat; and the effective thickness of the nanomaterial aggregate layer 24 can be uniform. Although the low density layer 55a is more fragile than the high density layer 55b, in this embodiment, the low density layer 55a is not easily affected by stress and its configuration can be maintained because the low density layer 55a is filled into the recess 43. Otherwise, the configurations, manufacturing methods, operations, and effects of this embodiment are similar to those of the first embodiment described above.

Although an example is illustrated in the descriptions of the embodiments described above in which the micro conductive body of the nanomaterial aggregate layer is a carbon nanotube (CNT), the invention is not limited thereto. The micro conductive body may be, for example, a carbon element such as a carbon sheet, a carbon tube, a carbon sphere, etc. More specifically, a carbon nanomaterial such as graphene, fullerene, or carbon nanoribbon may be used. A carbon nanotube may be any of single-walled, double-walled, or multi-walled. The micro conductive body also may be formed of a material other than carbon. An insulative particle may be disposed in the gap 32 of the nanomaterial aggregate layer 24 to adjust the resistance value of the entire nanomaterial aggregate layer 24.

Although an example is illustrated in the embodiments described above in which the nanomaterial aggregate layer is formed by coating and drying a nanomaterial in a liquid form with micro conductive bodies dispersed therein, the invention is not limited thereto. For example, the nanomaterial aggregate layer may be formed by dispersing the nanomaterial.

Further, although an example is illustrated in the embodiments described above in which the selection element includes a pin-type silicon diode layer 22, the invention is not limited thereto. For example, a MIM (metal-insulator-metal) diode or an element other than a diode may be used as the selection element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Moreover, above-mentioned embodiments can be combined mutually and can be carried out.

According to the embodiments described above, a nonvolatile memory device having high reliability and a method for manufacturing the same can be realized.

1. A nonvolatile memory device, comprising:
a first interconnect;
a nanomaterial aggregate layer provided on the first interconnect, the nanomaterial aggregate layer including an aggregation of a plurality of micro conductive bodies; and
a second interconnect provided on the nanomaterial aggregate layer,
at least a lower portion of the nanomaterial aggregate layer being disposed inside the second interconnect as viewed from above.

2. The device according to claim 1, wherein the entire nanomaterial aggregate layer is disposed inside the second interconnect as viewed from above.

3. The device according to claim 1, wherein the nanomaterial aggregate layer includes:
a lower layer; and
an upper layer having a density higher than a density of the lower layer.

4. The device according to claim 1, wherein no voids form in the nanomaterial aggregate layer.

5. The device according to claim 1, wherein the micro conductive body is a carbon nanotube.

6. The device according to claim 1, wherein:
an extension direction of the second interconnect intersects an extension direction of the first interconnect;
a first interconnect layer including a plurality of the first interconnects is stacked alternately with a second interconnect layer including a plurality of the second interconnects; and
the nanomaterial aggregate layer is at least a portion of a pillar provided between each of the first interconnects and each of the second interconnects.

7. The device according to claim 6, further comprising:
a selection element layer provided in the pillar between the first interconnect and the nanomaterial aggregate layer to select whether or not to allow a current to flow; and
an electrode layer provided between the selection element layer and the nanomaterial aggregate layer.

8. A method for manufacturing a nonvolatile memory device, comprising:
forming a pillar and an inter-layer insulating film on a first interconnect, a dummy layer being provided in at least an upper portion of the pillar, the inter-layer insulating film covering a side face of the pillar and leaving an upper face of the pillar exposed;
making a recess in an upper face of the inter-layer insulating film by removing the dummy layer;
forming a nanomaterial aggregate layer in the recess, the nanomaterial aggregate layer having gaps interposed between a plurality of micro conductive bodies; and
forming a second interconnect on the inter-layer insulating film and on the nanomaterial aggregate layer to cover the nanomaterial aggregate layer.

9. The method according to claim 8, wherein the forming of the second interconnect includes:
forming a conductive film on the inter-layer insulating film and on the nanomaterial aggregate layer; and
patterning the conductive film to cover the nanomaterial aggregate layer.

10. The method according to claim 8, wherein the forming of the nanomaterial aggregate layer includes:
coating a nanomaterial containing a plurality of the micro conductive bodies on the upper face of the inter-layer insulating film; and
drying the nanomaterial.

11. The method according to claim 10, wherein the forming of the nanomaterial aggregate layer includes multiply repeating the coating and the drying.

12. The method according to claim 8, wherein the forming of the nanomaterial aggregate layer includes:
coating a nanomaterial containing a plurality of the micro conductive bodies with a first thickness;
drying the nanomaterial coated with the first thickness;
coating the nanomaterial with a second thickness thinner than the first thickness; and
drying the nanomaterial coated with the second thickness.

13. The method according to claim 8, wherein a planarization is performed prior to the forming of the second interconnect to make an upper face of the nanomaterial aggregate layer the same plane as the upper face of the inter-layer insulating film.

14. The method according to claim 8, wherein the forming of the pillar and the inter-layer insulating film includes:
forming a selection element layer on the first interconnect;
forming an electrode layer on the selection element layer;
forming a dummy layer on the electrode layer;
forming the pillar by selectively removing the dummy layer, the electrode layer, and the selection element layer; and
forming the inter-layer insulating film around the pillar.

15. The method according to claim 8, wherein the forming of the pillar and the inter-layer insulating film includes:
forming a selection element layer on the first interconnect;
forming an electrode layer on the selection element layer;
patterning the pillar by selectively removing the electrode layer and the selection element layer;
forming the inter-layer insulating film around the pillar; and
forming the dummy layer by oxidizing an upper portion of the electrode layer.

16. The method according to claim 8, wherein the micro conductive body is a carbon nanotube.
